(19) United States
(12) Patent Application Publication
(10) Pub. No.: US 2026/0101534 A1
(43) Pub. Date: Apr. 9, 2026

(54) LDMOS TRANSISTOR, SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: KAI-CHUN CHANG, Hsinchu (TW); Yen-Chen LIAO, Hsinchu (TW); Po-Cheng HUANG, Hsinchu (TW)

(73) Assignee: Taiwan Semiconductor Manufacturing Company, Ltd., Hsinchu (TW)

(21) Appl. No.: 18/910,621

(22) Filed: Oct. 9, 2024

(51) Int. Cl. H01L 29/78; H01L 29/40; H01L 29/66

(52) U.S. Cl. CPC H10D 30/65; H10D 30/0227; H10D 30/0281; H10D 30/601; H10D 64/111

(57) ABSTRACT

A LDMOS transistor, a semiconductor structure and a manufacturing method thereof are provided. The LDMOS transistor includes a channel well, a lightly doped drift region, a source, a drain, a gate oxide layer, a gate, two STI structures, a RPO layer and a contact field plate. The gate oxide layer is disposed on the channel well and the lightly doped drift region. The gate is disposed on the gate oxide layer. The two STI structures are disposed at two sides of the lightly doped drift region. Each of the STI structures includes an insulator and a conductor. The RPO layer is only disposed on the lightly doped drift region. The contact field plate is disposed on the RPO layer. The conductors in the STI structures and the contact field plate are connected to the source.

### BACKGROUND

The disclosure relates in general to a semiconductor structure and a manufacturing method thereof, and more particularly to a LDMOS transistor, a semiconductor structure and a manufacturing method thereof.

The voltage withstand issue of the LDMOS transistor lies in the channel well and the gate oxide layer. It is needed to enhance the voltage withstand capability of the LDMOS transistor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a stereoscopic view of a laterally diffused MOS (LDMOS) transistor according to one embodiment of the present disclosure.

FIG. 2 shows a top view of the LDMOS transistor.

FIG. 3 shows a cross-sectional view along a section line 3-3′ of the LDMOS transistor in the FIG. 2.

FIG. 4 shows a cross-sectional view along a section line 4-4′ of the LDMOS transistor in the FIG. 2.

FIG. 5 shows a contact field plate control region in the LDMOS transistor.

FIG. 6 shows a STI structure according to one embodiment of the present disclosure.

FIG. 7 shows three semiconductor structures according to different embodiments of the present disclosure.

FIG. 8 shows different semiconductor structures according to different embodiments of the present disclosure.

FIG. 9 shows different semiconductor structures according to different embodiments of the present disclosure.

FIG. 10 shows different semiconductor structures according to different embodiments of the present disclosure.

FIG. 11 shows different semiconductor structures according to different embodiments of the present disclosure.

FIGS. 12A to 12H illustrate a manufacturing method of the semiconductor structure according to one embodiment of the present disclosure.

FIG. 13 shows an application for the LDMOS transistor.

FIG. 14 shows the power management integrated chip according to one embodiment of the present disclosure.

FIG. 15 illustrates the circuit diagram of the LDMOS transistor and the speaker.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “comprise,” “comprising,” “include,” “including,” “has,” “having,” etc. used in this specification are open-ended and mean “comprises but not limited.” The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

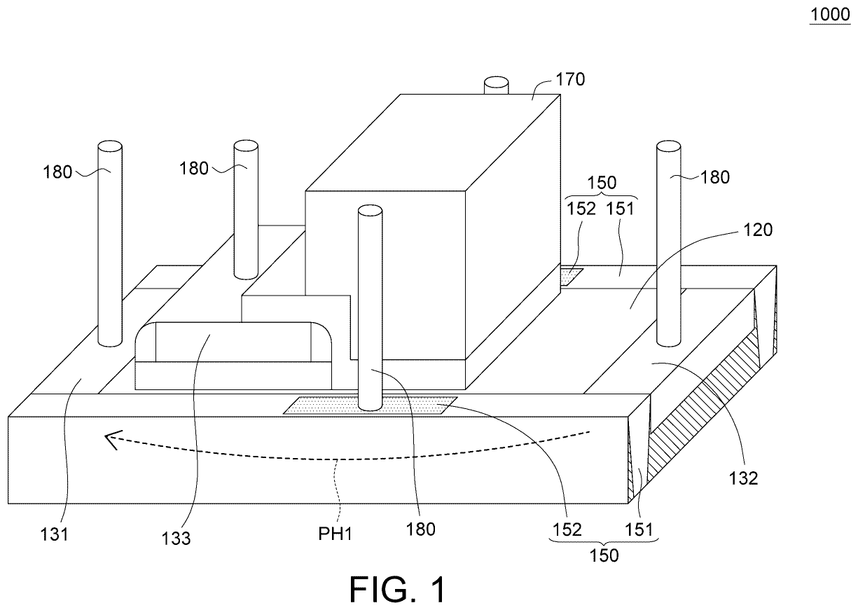

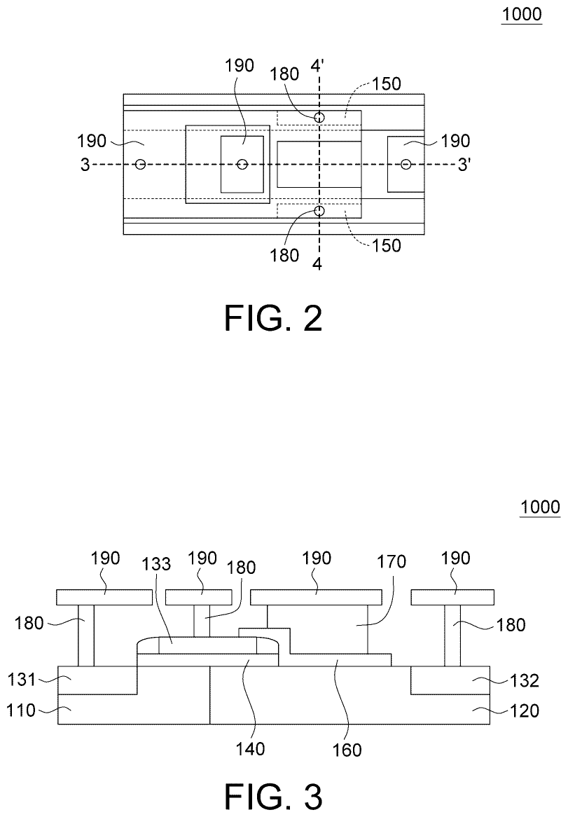

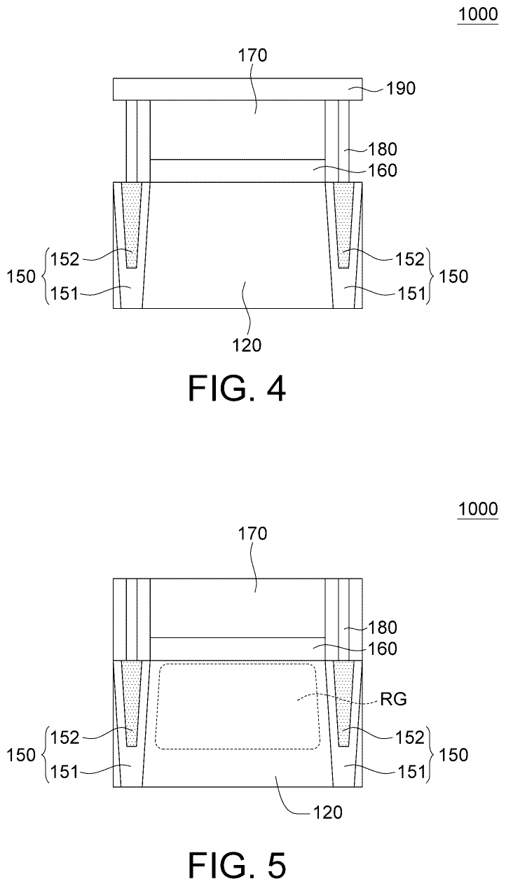

Please refer to FIGS. 1 to 4. FIG. 1 shows a stereoscopic view of a laterally diffused MOS (LDMOS) transistor 1000 according to one embodiment of the present disclosure. FIG. 2 shows a top view of the LDMOS transistor 1000. FIG. 3 shows a cross-sectional view along a section line 3-3′ of the LDMOS transistor 1000 in the FIG. 2. FIG. 4 shows a cross-sectional view along a section line 4-4′ of the LDMOS transistor 1000 in the FIG. 2.

As shown in the FIG. 3, the LDMOS transistor 1000 includes a channel well 110, a lightly doped drift region 120, a source 131, a drain 132, a gate oxide layer 140, a gate 133, two shallow trench isolation (STI) structures 150 (shown in the FIG. 2), a resistive protective oxide (RPO) layer 160 and a contact field plate 170. The source 131 is disposed in the channel well 110. The drain 132 is disposed in the lightly doped drift region 120. The gate oxide layer 140 is disposed on the channel well 110 and the lightly doped drift region 120. The gate 133 is disposed on the gate oxide layer 140. The two STI structures 150 are disposed at two sides of entire of the LDMOS transistor 1000. For example, the two STI structures 150 are disposed at two sides of the lightly doped drift region 120. The resistive protective oxide (RPO) layer 160 is only disposed on the lightly doped drift region 120. The contact field plate 170 is disposed on the RPO layer 160.

As shown in the FIG. 4, each of the STI structures 150 includes an insulator 151 and a conductor 152. The insulator 151 surrounds the conductor 152. The conductors 152 in the STI structures are the one that are disposed at two sides of the lightly doped drift region 120. The conductors 152 in the STI structures 150 and the contact field plate 170 are connected to the source 131. In detail, the conductors 152 are connected to a metal layer 190 via contacts 180, and the contact field plate 170 is connected to the metal layer 190. The metal layer 190 is connected to the source 131.

Please refer to FIGS. 1 and 5. FIG. 5 shows a contact field plate control region RG in the LDMOS transistor 1000. As shown in the FIG. 1, the conductor 151 of the STI structures 150 is disposed at two sides of a path PH1 from the drain 132 to the source 131. Because the conductors 151 and the contact field plate 170 are connected to the source 131, the contact field plate control the region RG being extended downward to block the high voltage from the drain 132. Therefore, the breakdown voltage of the LDMOS transistor 1000 could be increased.

The insulator 151 in each of the STI structures 150 could be a single-layer structure or a multiple-layers structure; the conductor 152 in each of the STI structures 150 could be a single-layer structure or a multiple-layers structure.

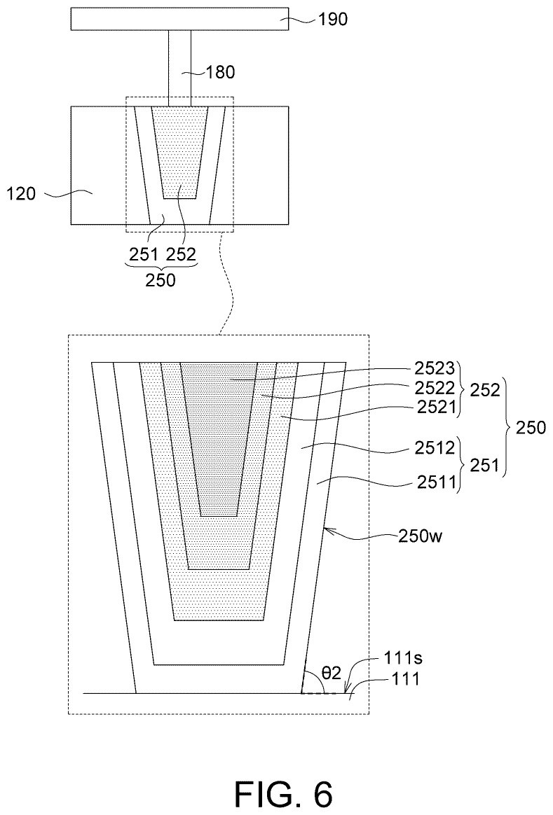

Please refer to FIG. 6, which shows a STI structure 250 according to one embodiment of the present disclosure. In this example, the insulator 251 in each of the STI structures 250 is a multiple-layers structure; the conductor 252 in each of the STI structures 250 is a multiple-layers structure. For example, the insulator 251 includes a first insulating layer 2511 and a second insulating layer 2512. The second insulating layer 2512 is disposed on the first insulating layer 2511. The material of the first insulating layer 2512 is, for example, SiO, SiON, Si3N4, SiN, HfO2, ZrO2, MgO2, Al2O3, CaO, ZrSiO4, HfSiO4, Y2O3, La2O3, LaLuO2, SrO, Ta2O5, BaO, TiO2, Ta2O5, or the combination thereof. The material of the second insulating layer 2512 is, for example, SiO, SiON, Si3N4, SiN, HfO2, ZrO2, MgO2, Al2O3, CaO, ZrSiO4, HfSiO4, Y2O3, La2O3, LaLuO2, SrO, Ta2O5, BaO, TiO2, Ta2O5 or the combination thereof. A thickness of the first insulating layer 2511 or the second insulating layer is 50 nm to 200 nm.

The conductor 252 includes a first conducting layer 2521, a second conducting layer 2522 and a third conducting layer 2522. The second conducting layer 2522 is disposed on the first conducting layer 2521. The third conducting layer 2523 is disposed on the second conducting layer 2522. The material of the first conducting layer 2521, the second conducting layer 2522 and the third conducting layer 2523 is, for example, Ti, TiN, TaN, W, Ni, Co, Pd, Pt, Zr, Cr, Hf, Ru, Ir, Ta or the combination thereof. A thickness of the first conducting layer 2521, the second conducting layer 2522 or the third conducting layer 2523 is 50 nm to 200 nm.

The STI structure 250 is disposed on the substrate 111. An angle θ2 between a lateral wall 250w of the STI structure 250 and a top surface 111s of a substrate 111 is 30 to 150 degrees.

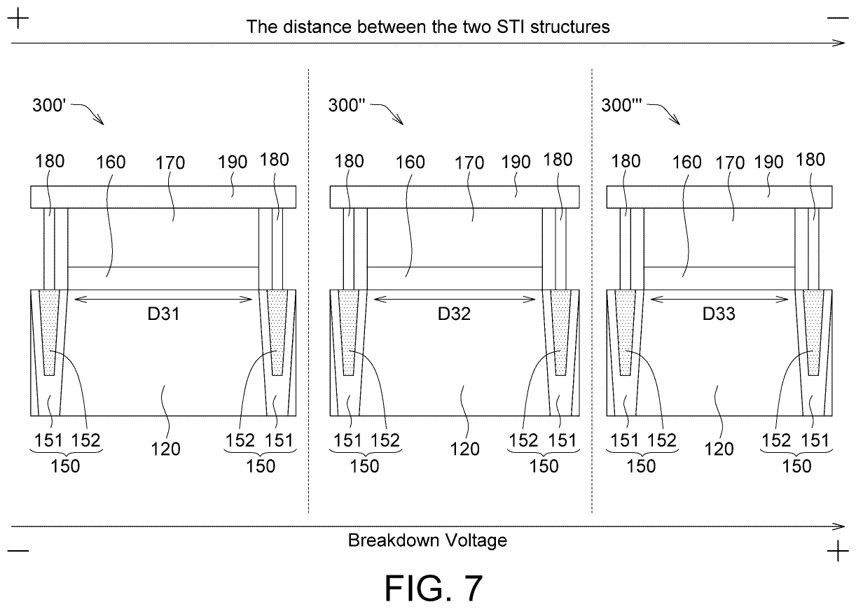

Please refer to FIG. 7, which shows three semiconductor structures 300′, 300″ and 300″′ according to different embodiments of the present disclosure. Comparing the semiconductor structures 300′ and 300″ in the FIG. 7, the distance D32 is shorter than the distance D31. The two STI structures 150 with the shorter distance D32 could have a stronger impact on the contact field plate 170, so the breakdown voltage would be increased more.

Comparing the semiconductor structures 300″ and 300″′ in the FIG. 7, the distance D33 is shorter than the distance D32. The two STI structures 150 with the shorter distance D33 could have a stronger impact on the contact field plate 170, so the breakdown voltage would be increased more.

That is to say, the shorter the distance between the two STI structures 150 is, the more the breakdown voltage will be increased.

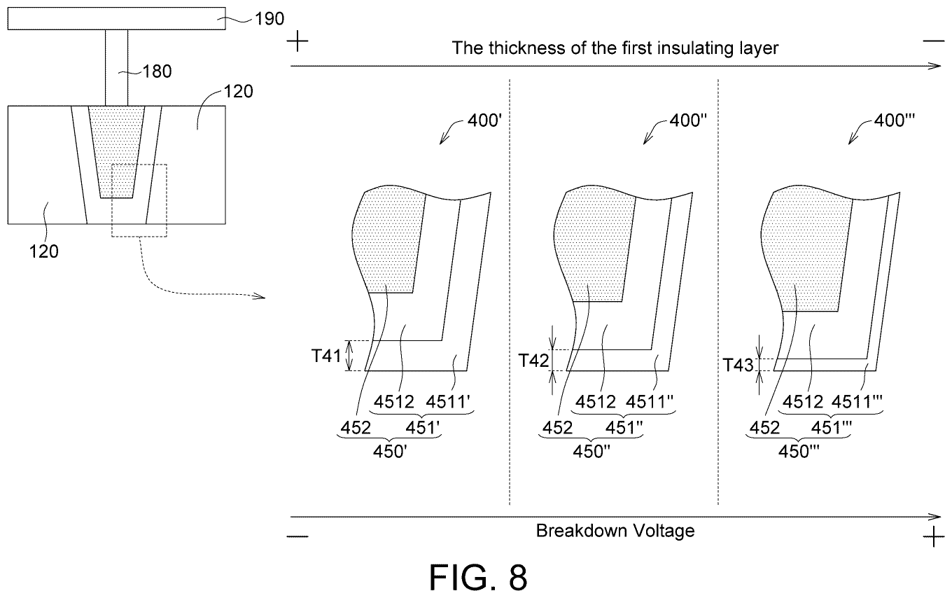

Please refer to FIG. 8, which shows different semiconductor structures 400′, 400″, 400″′ according to different embodiments of the present disclosure. The semiconductor structure 400′ includes a STI structure 450′ including an insulator 451′ and a conductor 452. The insulator 451′ includes a first insulating layer 4511′ and a second insulating layer 4512. The semiconductor structure 400″ includes a STI structure 450″ including an insulator 451″ and the conductor 452. The insulator 451″ includes a first insulating layer 4511″ and the second insulating layer 4512. The semiconductor structure 400″′ includes a STI structure 450″′ including an insulator 451″′ and the conductor 452. The insulator 451″′ includes a first insulating layer 4511″′ and the second insulating layer 4512.

Comparing the semiconductor structures 400′ and 400″ in the FIG. 8, a thickness T42 of the first insulating layer 4511″ is smaller than a thickness T41 of the first insulating layer 4511′. The first insulating layer 4511″ with the thinner thickness T42 could make the conductor 452 closer to the lightly doped drift region 120 to enhance the influence of the contact field plate 170, and thus the breakdown voltage would be increased more.

Comparing the semiconductor structures 400″ and 400″′ in the FIG. 8, a thickness T43 of the first insulating layer 4511″′ is smaller than the thickness T42 of the first insulating layer 4511″. The first insulating layer 4511″′ with the thinner thickness T43 could make the conductor 452 closer to the lightly doped drift region 120 to enhance the influence of the contact field plate 170, and thus the breakdown voltage would be increased more.

That is to say, the thinner the thickness of the first insulating layer is, the more the breakdown voltage will be increased.

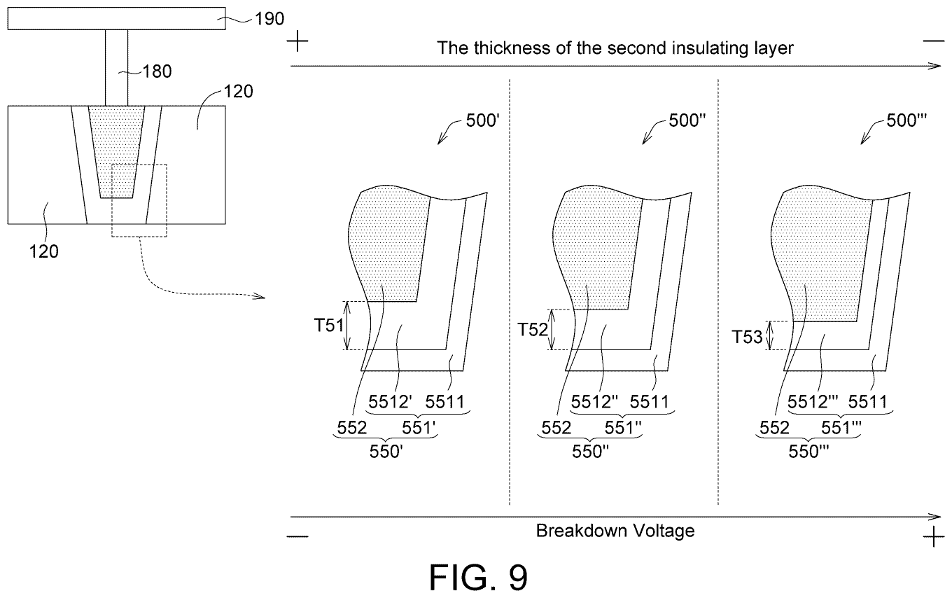

Please refer to FIG. 9, which shows different semiconductor structures 500′, 500″, 500″′ according to different embodiments of the present disclosure. The semiconductor structure 500′ includes a STI structure 550′ including an insulator 551′ and a conductor 552. The insulator 551′ includes a first insulating layer 5511 and a second insulating layer 5512′. The semiconductor structure 500″ includes a STI structure 550″ including an insulator 551″ and the conductor 552. The insulator 551″ includes the first insulating layer 5511 and a second insulating layer 5512″. The semiconductor structure 500″′ includes a STI structure 550″′ including an insulator 551″′ and the conductor 552. The insulator 551″′ includes the first insulating layer 4511 and a second insulating layer 4512″′.

Comparing the semiconductor structures 500′ and 500″ in the FIG. 9, a thickness T52 of the second insulating layer 5512″ is smaller than a thickness T51 of the second insulating layer 5515′. The second insulating layer 5512″ with the thinner thickness T52 could make the conductor 552 closer to the lightly doped drift region 120 to enhance the influence of the contact field plate 170, and thus the breakdown voltage would be increased more.

Comparing the semiconductor structures 500″ and 500″′ in the FIG. 9, a thickness T53 of the second insulating layer 5512″′ is smaller than the thickness T52 of the second insulating layer 5512″. The second insulating layer 5512″′ with the thinner thickness T53 could make the conductor 552 closer to the lightly doped drift region 120 to enhance the influence of the contact field plate 170, and thus the breakdown voltage would be increased more.

That is to say, the thinner the thickness of the second insulating layer is, the more the breakdown voltage will be increased.

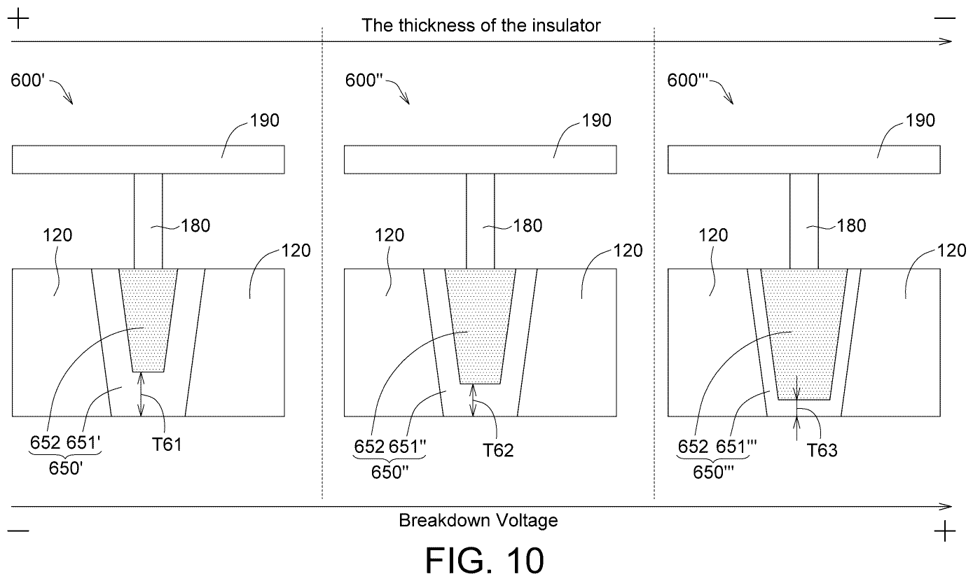

Please refer to FIG. 10, which shows different semiconductor structures 600′, 600″, 600″′ according to different embodiments of the present disclosure. The semiconductor structure 600′ includes a STI structure 650′ including an insulator 651′ and a conductor 652. The semiconductor structure 600″ includes a STI structure 650″ including an insulator 651″ and the conductor 652. The semiconductor structure 600″′ includes a STI structure 650″′ including an insulator 651″′ and the conductor 652.

Comparing the semiconductor structures 600′ and 600″ in the FIG. 10, a thickness T62 of the insulator 651″ is smaller than a thickness T61 of the insulator 651′. The insulator 651″ with the thinner thickness T62 could make the conductor 652 closer to the lightly doped drift region 120 to enhance the influence of the contact field plate 170, and thus the breakdown voltage would be increased more.

Comparing the semiconductor structures 600″ and 600″′ in the FIG. 10, a thickness T63 of the insulator 651″′ is smaller than the thickness T62 of the insulator 651″. The insulator 651″′ with the thinner thickness T63 could make the conductor 652 closer to the lightly doped drift region 120 to enhance the influence of the contact field plate 170, and thus the breakdown voltage would be increased more.

That is to say, the thinner the thickness of the insulator is, the more the breakdown voltage will be increased.

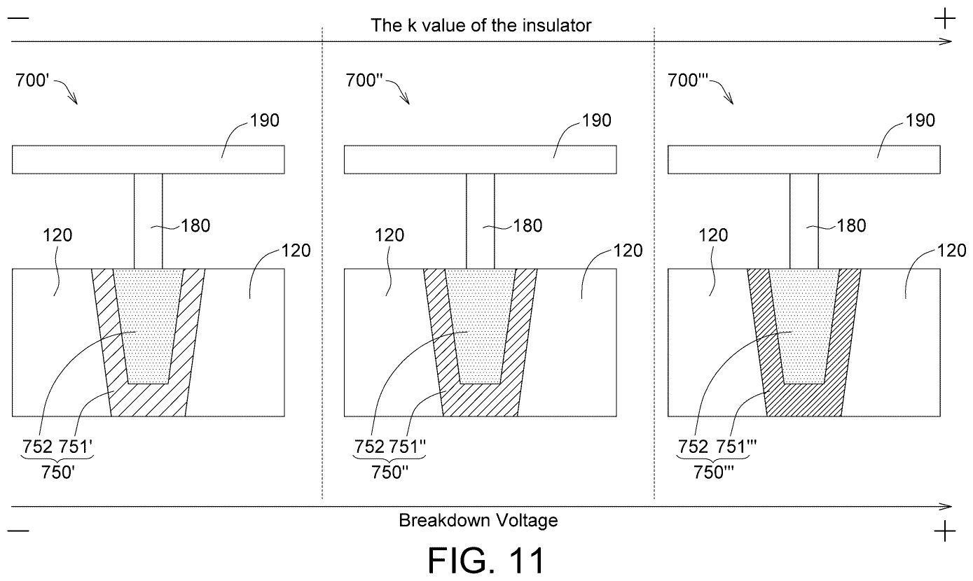

Please refer to FIG. 11, which shows different semiconductor structures 700′, 700″, 700″′ according to different embodiments of the present disclosure. The semiconductor structure 700′ includes a STI structure 750′ including an insulator 751′ and a conductor 752. The semiconductor structure 700″ includes a STI structure 750″ including an insulator 751″ and the conductor 752. The semiconductor structure 700″′ includes a STI structure 750″′ including an insulator 751″′ and the conductor 752.

Comparing the semiconductor structures 700′ and 700″ in the FIG. 11, a k value of the insulator 751″ is larger than a k value of the insulator 751′. The insulator 751″ with the larger k value could enhance the influence of the contact field plate 170, and thus the breakdown voltage would be increased more.

Comparing the semiconductor structures 700″ and 700″′ in the FIG. 11, a k value of the insulator 751″′ is larger than the k value of the insulator 751″. The insulator 751″′ with the larger k value could enhance the influence of the contact field plate 170, and thus the breakdown voltage would be increased more.

That is to say, the higher the k value of the insulator is, the more the breakdown voltage will be increased.

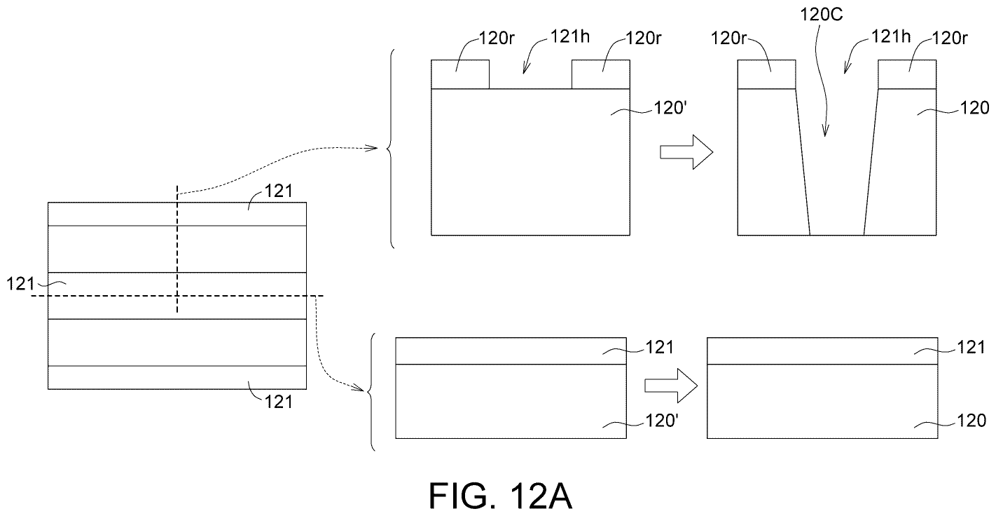

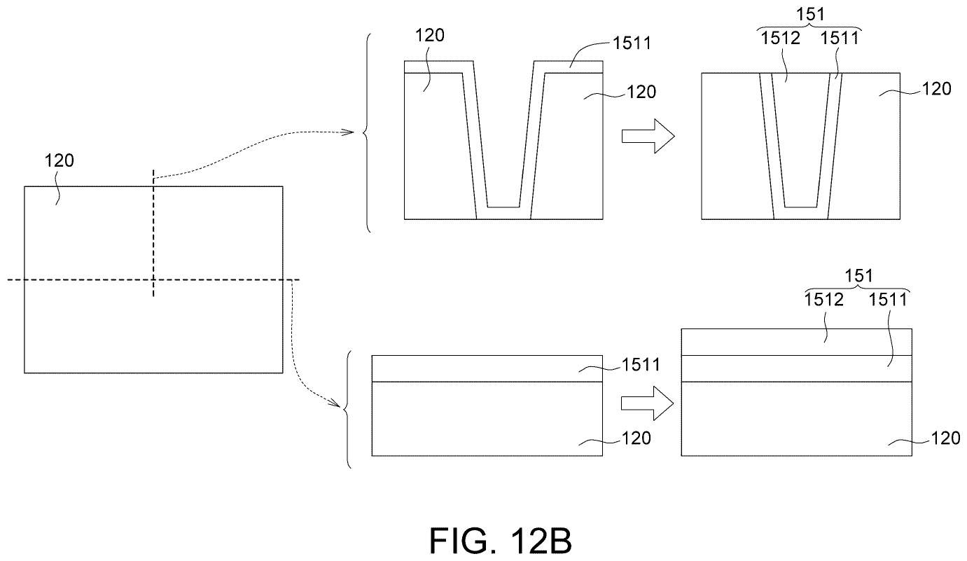

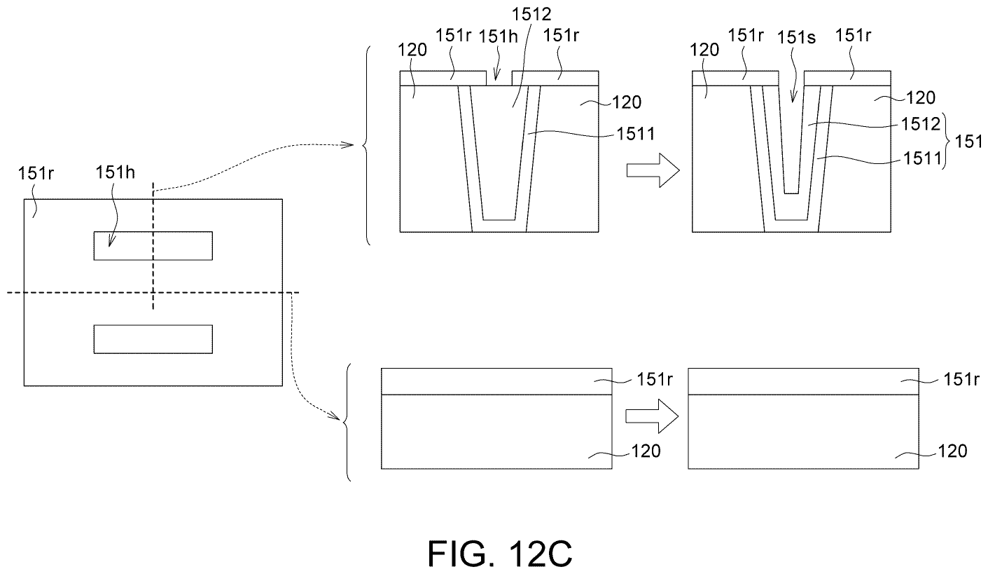

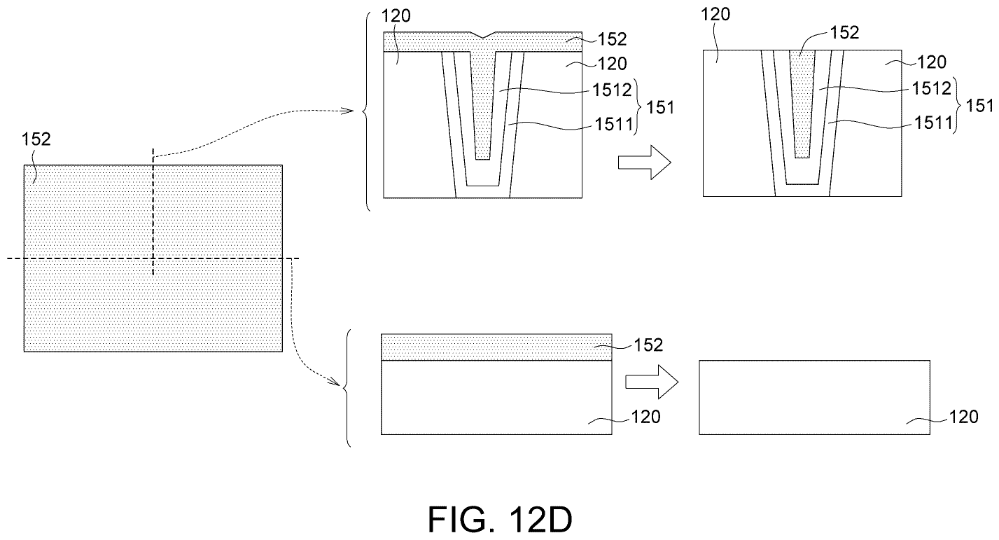

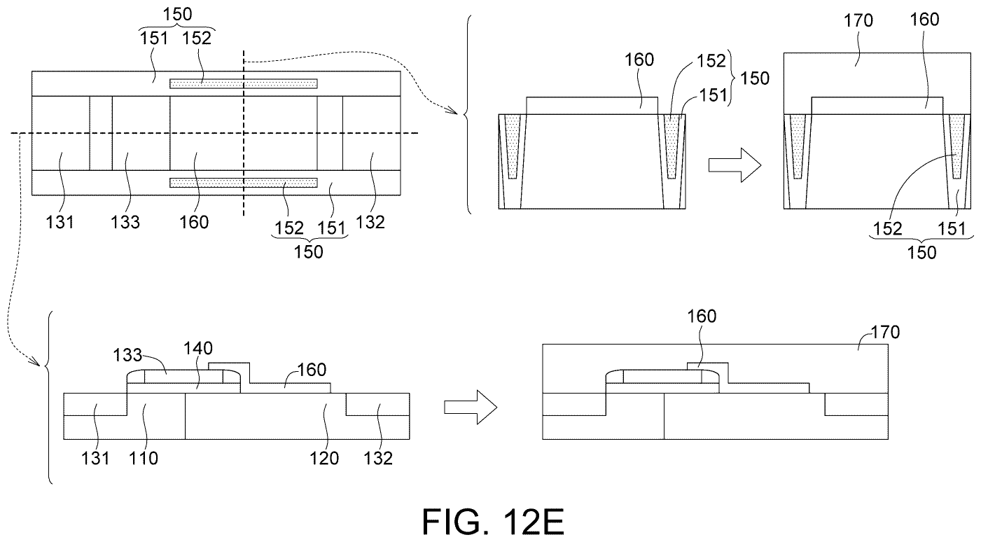

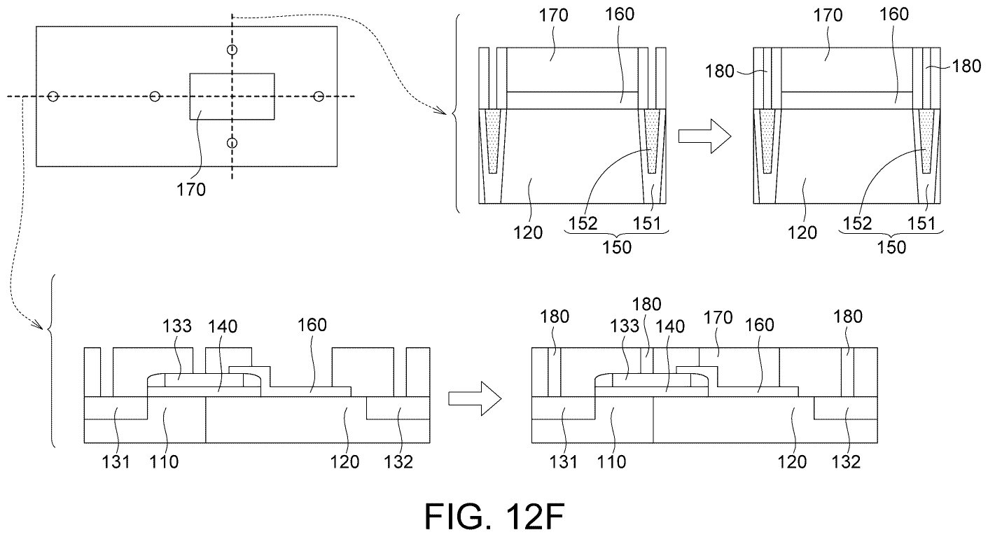

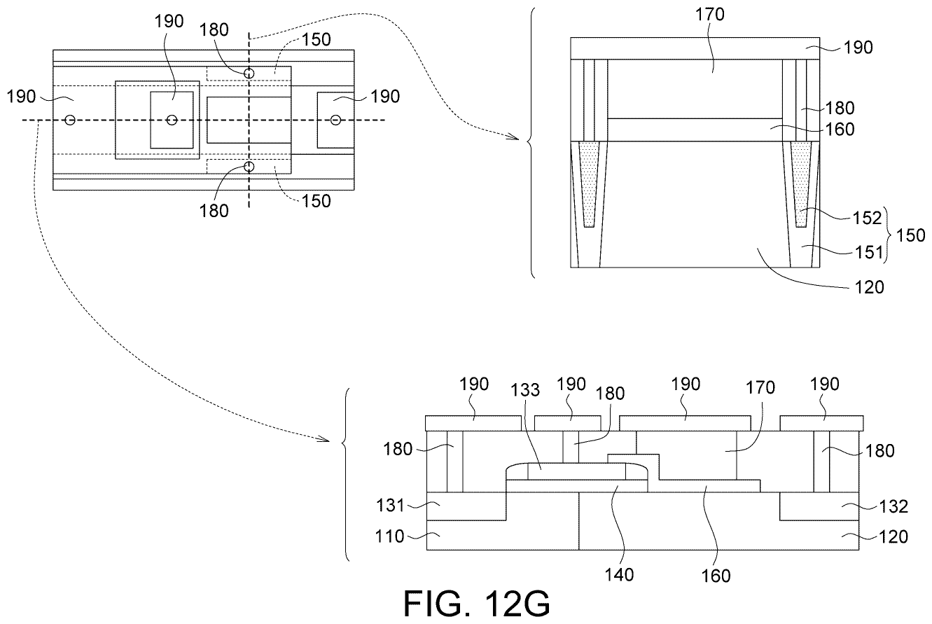

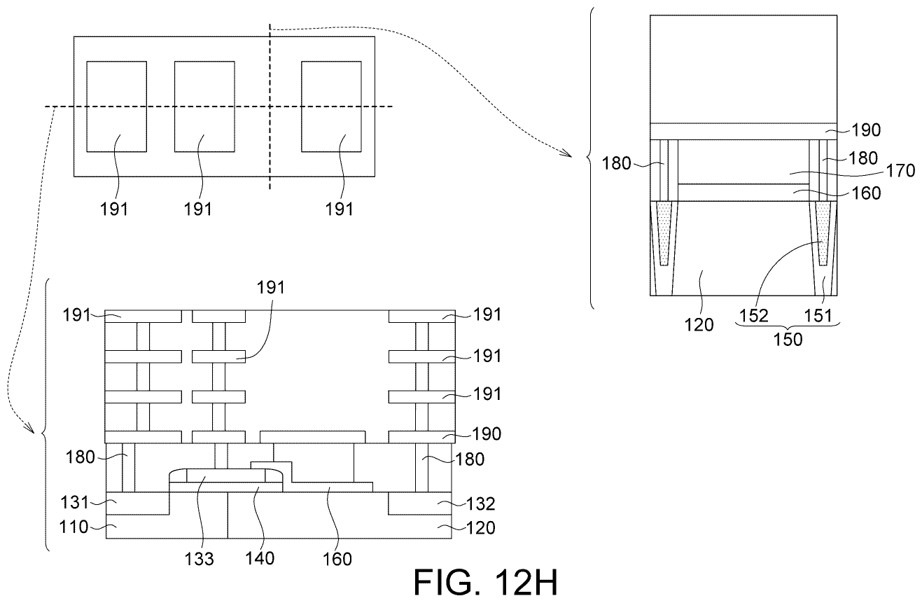

Please refer to FIGS. 12A to 12H, which illustrate a manufacturing method of the semiconductor structure according to one embodiment of the present disclosure. As shown in the FIG. 12A, an active region 120′ is patterned to form a concave 120C. For example, a photoresist layer 120r is patterned via a lithography process to form an opening 121h, and then the active region 120′ is etched by using the patterned photoresist layer 120r as a mask to form the concave 120C.

As shown in the FIG. 12B, the insulator 151 is formed in the concave 120C. In detail, as shown in the FIG. 12B, a first insulating layer 1511 is formed in the concave 120C. Then, the first insulating layer 1511 is covered by a second insulating layer 1512. Afterward, the first insulating layer 1511 and the second insulating layer 1512 are polished and the insulator 151 is formed.

Next, as shown in the FIG. 12C, the insulator 151 is patterned to form a slot 151s. In detail, a photoresist layer 151r is patterned via a lithography process to form an opening 151h, and then the second insulating layer 1512 is etched by using the patterned photoresist layer 151r as a mask to form the slot 151s.

Then, as shown in the FIG. 12D, the conductor 152 is formed in the slot 151s. The insulator 151 and the conductor 152 form the shallow trench isolation (STI) structure 150. In detail, the material of the conductor 152 is filled in the slot 151s and on the top of the semiconductor structure. Then the material of the conductor 152 is polished.

The conductor 152 shown in the FIG. 12D is a single layer structure. In one embodiment, the conductor 152 could be a multi-layers structure.

Next, as shown in the FIG. 12E, the resistive protective oxide (RPO) layer 160 is formed on the lightly doped drift region 120 and the contact field plate 170 is formed on the RPO layer 160.

Then, as shown in the FIG. 12F, the contacts 180 are formed on the STI structures 150.

Next, as shown in the FIG. 12G, the metal layer 190 is formed on the contacts 180. The metal layer 190 is connected to the source 131.

Then, as shown in the FIG. 12H, a plurality of BEOL metal layers 191 are formed.

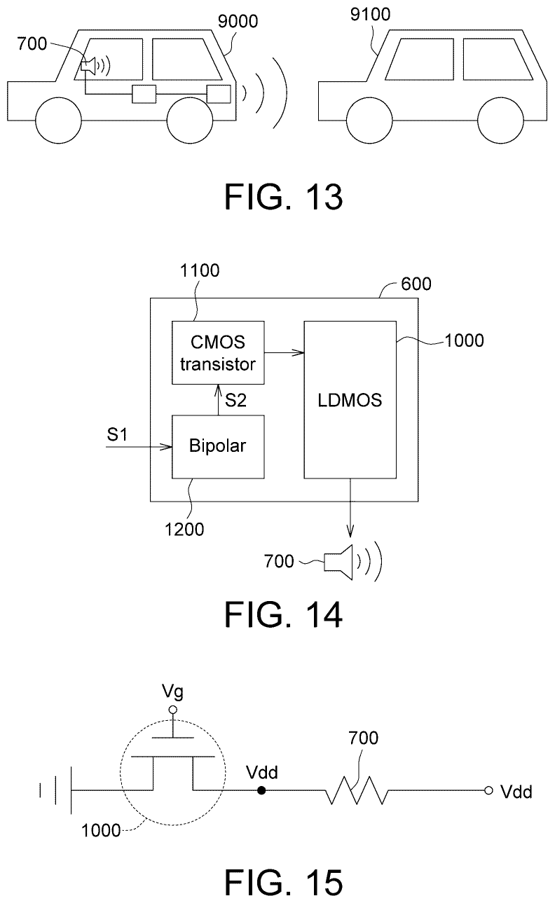

Please refer to FIG. 13, which shows an application for the LDMOS transistor 1000. In a car 9000, a sensor 800 could be used to detect whether another car 9000 is close. If the sensor 800 detects that another car 9100 is close, then a speaker 700 could generate a warning sound. A power management integrated chip 600 including the LDMOS transistor 1000 is connected between the speaker 700 and the sensor 800.

Please refer to FIG. 14, which shows the power management integrated chip 600 according to one embodiment of the present disclosure. When an analog signal S1 is inputted from the sensor 800, a bipolar 1200 converts and amplifies the analog signal S1 into a digital signal S2. When the CMOS transistor 1100 receives the digital signal S2, the CMOS transistor 1100 determined whether any car is close or not according to digital signal S2. Then, the CMOS transistor 1100 turns on or turns off the LDMOS transistor 1000 according to whether any car is close or not. Next, the LDMOS transistor 1000 drives the speaker 700 when the LDMOS transistor is turned on.

Please refer to FIG. 15, which illustrates the circuit diagram of the LDMOS transistor 1000 and the speaker 700. When the LDMOS transistor 1000 is turned off, the gate voltage Vg is controlled at 0V, but the drain voltage Vdd is kept at high. The LDMOS transistor 1000 needs to withstand large voltage from the drain voltage Vdd.

According to the embodiments described above, the Shallow Trench Isolation (STI) structure 150 and the contact field plate (CFP) 170 of the LDMOS transistor 1000 is merged to withstand large voltage from the drain voltage Vdd and improve the breakdown voltage.

According to one example embodiment, a laterally diffused MOS (LDMOS) transistor is provided. The LDMOS transistor includes a channel well, a lightly doped drift region, a source, a drain, a gate oxide layer, a gate, two shallow trench isolation (STI) structures, a resistive protective oxide (RPO) layer and a contact field plate. The source is disposed in the channel well. The drain is disposed in the channel well. The gate oxide layer is disposed on the channel well and the lightly doped drift region. The gate is disposed on the gate oxide layer. The two shallow trench isolation (STI) structures are disposed at two sides of the lightly doped drift region. Each of the STI structures includes an insulator and a conductor. The resistive protective oxide (RPO) layer is only disposed on the lightly doped drift region. The contact field plate is disposed on the RPO layer. The conductors in the STI structures and the contact field plate are connected to the source.

Based on the LDMOS transistor described in the previous embodiments, the insulator surrounds the conductor.

Based on the LDMOS transistor described in the previous embodiments, the conductor in each of the STI structures is a single-layer structure.

Based on the LDMOS transistor described in the previous embodiments, the conductor in each of the STI structures is a multiple-layers structure.

Based on the LDMOS transistor described in the previous embodiments, the insulator in each of the STI structures is a single-layer structure.

Based on the LDMOS transistor described in the previous embodiments, the insulator in each of the STI structures is a multiple-layers structure.

Based on the LDMOS transistor described in the previous embodiments, the STI structures are disposed on a substrate, an angle between a lateral wall of each of the STI structures and a top surface of the substrate is 30 to 150 degrees.

Based on the LDMOS transistor described in the previous embodiments, a width between the STI structures is 200 nm to 800 nm.

Based on the LDMOS transistor described in the previous embodiments, the insulator in each of the STI structures includes a first insulating layer and a second insulating layer disposed on the first insulating layer, and a thickness of the first insulating layer is 50 nm to 200 nm.

Based on the LDMOS transistor described in the previous embodiments, the insulator in each of the STI structures includes a first insulating layer and a second insulating layer disposed on the first insulating layer, and a thickness of the second insulating layer is 50 nm to 200 nm.

According to another example embodiment, a manufacturing method of a semiconductor structure is provided. The manufacturing method of the semiconductor structure includes: patterning an active region to form a concave; forming an insulator in the concave; patterning the insulator to form a slot; and forming a conductor in the slot. The insulator and the conductor form a shallow trench isolation (STI) structure.

Based on the manufacturing method of the semiconductor structure described in the previous embodiments, the step of forming the insulator in the concave, the conductor is a single-layer structure.

Based on the manufacturing method of the semiconductor structure described in the previous embodiments, in the step of forming the insulator in the concave, the conductor is a multiple-layers structure.

Based on the manufacturing method of the semiconductor structure described in the previous embodiments, the step of forming the conductor in the slot, the conductor is a single-layer structure.

Based on the manufacturing method of the semiconductor structure described in the previous embodiments, in the step of forming the conductor in the slot, the conductor is a multiple-layers structure.

According to another example embodiment, a semiconductor structure is provided. The semiconductor structure includes a lightly doped drift region, two shallow trench isolation (STI) structures, a resistive protective oxide (RPO) layer and a contact field plate. The two shallow trench isolation (STI) structures are disposed at two sides of the lightly doped drift region. Each of the STI structures includes an insulator and a conductor. The resistive protective oxide (RPO) layer is only disposed on the lightly doped drift region. The contact field plate is disposed on the RPO layer. The conductors in the STI structures and the contact field plate are connected to a source.

Based on the semiconductor structure described in the previous embodiments, the insulator surrounds the conductor.

Based on the semiconductor structure described in the previous embodiments, the conductor in each of the STI structures is a single-layer structure.

Based on the semiconductor structure described in the previous embodiments, the conductor in each of the STI structures is a multiple-layers structure.

Based on the semiconductor structure described in the previous embodiments, the insulator in each of the STI structures is a single-layer structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A laterally diffused MOS (LDMOS) transistor, comprising:
a channel well;
a lightly doped drift region;
a source, disposed in the channel well;
a drain, disposed in the channel well;
a gate oxide layer, disposed on the channel well and the lightly doped drift region;
a gate, disposed on the gate oxide layer;
two shallow trench isolation (STI) structures, disposed at two sides of the lightly doped drift region, wherein each of the STI structures includes an insulato1 and a conductor;
a resistive protective oxide (RPO) layer, only disposed on the lightly doped drift region; and
a contact field plate, disposed on the RPO layer;
wherein the conductors in the STI structures and the contact field plate are connected to the source.

2. The LDMOS transistor according to claim 1, wherein the insulator surrounds the conductor.

3. The LDMOS transistor according to claim 1, wherein the conductor in each of the STI structures is a single-layer structure.

4. The LDMOS transistor according to claim 1, wherein the conductor in each of the STI structures is a multiple-layers structure.

5. The LDMOS transistor according to claim 1, wherein the insulator in each of the STI structures is a single-layer structure.

6. The LDMOS transistor according to claim 1, wherein the insulator in each of the STI structures is a multiple-layers structure.

7. The LDMOS transistor according to claim 1, wherein the STI structures are disposed on a substrate, an angle between a lateral wall of each of the STI structures and a top surface of the substrate is 30 to 150 degrees.

8. The LDMOS transistor according to claim 1, wherein a width between the STI structures is 200 nm to 800 nm.

9. The LDMOS transistor according to claim 1, wherein the insulator in each of the STI structures includes a first insulating layer and a second insulating layer disposed on the first insulating layer, and a thickness of the first insulating layer is 50 nm to 200 nm.

10. The LDMOS transistor according to claim 1, wherein the insulator in each of the STI structures includes a first insulating layer and a second insulating layer disposed on the first insulating layer, and a thickness of the second insulating layer is 50 nm to 200 nm.

11. A manufacturing method of a semiconductor structure, comprising:
patterning an active region to form a concave;
forming an insulator in the concave;
patterning the insulator to form a slot; and
forming a conductor in the slot, wherein the insulator and the conductor form a shallow trench isolation (STI) structure.

12. The manufacturing method of the semiconductor structure according to claim 11, wherein the step of forming the insulator in the concave, the conductor is a single-layer structure.

13. The manufacturing method of the semiconductor structure according to claim 11, wherein in the step of forming the insulator in the concave, the conductor is a multiple-layers structure.

14. The manufacturing method of the semiconductor structure according to claim 11, wherein the step of forming the conductor in the slot, the conductor is a single-layer structure.

15. The manufacturing method of the semiconductor structure according to claim 11, wherein in the step of forming the conductor in the slot, the conductor is a multiple-layers structure.

16. A semiconductor structure, comprising:
a lightly doped drift region;
two shallow trench isolation (STI) structures, disposed at two sides of the lightly doped drift region, wherein each of the STI structures includes an insulator and a conductor;
a resistive protective oxide (RPO) layer, only disposed on the lightly doped drift region; and
a contact field plate, disposed on the RPO layer;
wherein the conductors in the STI structures and the contact field plate are connected to a source.

17. The semiconductor structure according to claim 16, wherein the insulator surrounds the conductor.

18. The semiconductor structure according to claim 16, wherein the conductor in each of the STI structures is a single-layer structure.

19. The semiconductor structure according to claim 16, wherein the conductor in each of the STI structures is a multiple-layers structure.

20. The semiconductor structure according to claim 16, wherein the insulator in each of the STI structures is a single-layer structure.
